(19) United States
(12) Patent Application Publication
(10) Pub. No.: US 2010/0300876 A1
(43) Pub. Date: Dec. 2, 2010

(54) Cobalt-iron alloy sputtering target with high pass through flux and method for manufacturing the same

(75) Inventors: Shang-Chieh Hou, Tainan (TW); Hui-Wen Cheng, Tainan (TW)

Correspondence Address: COOPER & DUNHAM, LLP, 30 Rockefeller Plaza, 20th Floor, NEW YORK, NY, 10112, US

(73) Assignee: SOLAR APPLIED MATERIALS TECHNOLOGY CORP.

(21) Appl. No.: 12/454,916

(22) Filed: May 26, 2009

(51) Int. Cl. C23C 14/34; C22F 1/00; C21D 1/00

(52) U.S. Cl. 204/298.13; 148/538; 148/540

(57) ABSTRACT

A cobalt-iron alloy sputtering target is made by melting and casting process and consists of cobalt, iron and additive metal, wherein the cobalt has an increased pass through flux content in the cobalt-iron alloy sputtering target and the additive metal has a content from 8 at % 20 at % and is at least one metal selected from the group consisting of tantalum, zirconium, niobium, hafnium, aluminum and chromium. The cobalt-iron alloy sputtering target has increased pass through flux.

### BACKGROUND OF THE INVENTION

1. Field of Invention

The present invention relates to a cobalt-iron alloy sputtering target, and more particularly to a cobalt-iron alloy sputtering target with high pass through flux (PTF), which is made by a simple melting and casting process.

2. Description of the Related Art

High recording density media is used to conveniently store large amounts of data and information. Increasing use and dependence has generated a demand for the high recording density media obtaining ultra-high recording density. A traditional recording media uses longitudinal magnetic recording (LMR) technology but has a density limit. Subsequently, perpendicular magnetic recording (PMR) technology has been developed. The PMR has a recording layer and a soft magnetic layer. Because of the soft magnetic layer, writing efficiency is improved, demagnetization effect is lowered and thermal stability of the recording layer is increased.

For providing improved characteristics of the soft magnetic layer, the soft magnetic layer consists of amorphous soft magnetic alloy, which may be iron-cobalt-boron (Fe—Co—B) alloy, cobalt-zirconium-niobium (Co—Zr—Nb) alloy or cobalt-iron-zirconium (Co—Fe—Zr) alloy. The Co—Fe based alloys are of primary concern to industry.

General sputtering methods including direct-current sputtering, radio frequency (RF) sputtering, triode sputtering or the like have low sputtering yield because low ionization density of gaseous molecules are emitted during discharge. Therefore, magnetic enhanced sputtering is a principal method for depositing a thin film. The magnetic enhanced sputtering technology allows electrons to move in a spiral path around a line of magnetic force by adding a magnetic field, so more electrons impact gaseous molecules, which increases ionization density and sputtering yield. Furthermore, magnetic enhanced sputtering can be conducted under low pressure to obtain a thin film with improved quality. Additionally, the magnetic field induces the electrons to stray from a substrate to be deposited, therefore, the magnetic enhanced sputtering can be used for a substrate that cannot endure high temperature.

However, if an iron magnetic sputtering target is used in the magnetic enhanced sputtering, the iron magnetic sputtering target cannot work normally because of magnetic shielding effects of the iron magnetic sputtering target. Moreover, magnetic focusing occurs when using the iron magnetic sputtering target, which forms recesses in a surface of the sputtering target and lowers utility rate of the iron magnetic sputtering target. Such problems are related to a pass through flux (PTF) and increasing the PTF is one solution.

As used herein, “pass through flux (PTF)” indicates a ratio of transmitted magnetic field to applied magnetic field. A measurement technique of PTF can be found in ASTM Standard F1761“standard test method for pass through flux of circular magnetic sputtering targets”. A PTF value of 100% is indicative of a non-magnetic material and an inverse correlation typically exists between PTF and maximum permeability.

Conventionally, vacuum inductive melting (VIM) is used to produce a soft magnetic sputtering target with a thickness of 3 mm˜7 mm and PTF less than 15%.

US publication No. 20030228238 discloses a target that is formed by blending powders with different PTF and consolidating the powders with a powder metallurgy process to form a target having macroscopically magnetic properties. The material with high PTF provides high flux paths for magnetic fields to pass through the target.

US publication No. 20080083616 discloses that a Co—Fe based soft magnetic sputtering target has improved PTF when the Co—Fe based soft magnetic sputtering target has a phase composed of HCP—Co and an alloy phase composed mainly of Fe. However, the target is still made by a metallurgy process.

When comparing a metallurgy process with a melting and casting process, the metallurgy process is complicated, requires higher cost and cannot easily be used to manufacture sputtering targets on a large-scale. Therefore, the metallurgy process cannot be used broadly. Inversely, the melting and casting process is simple, requires lower cost and can be used for producing targets to a large variety of scales and shapes. Furthermore, the melting and casting process can be used to produce a large amount of targets simultaneously and continuously, so the melting and casting process has a broad application.

What is needed is a cobalt-iron alloy sputtering target to mitigate or obviate the aforementioned disadvantage of techniques used heretofore.

### SUMMARY OF THE INVENTION

A primary objective of an embodiment of the present invention is to provide a cobalt-iron alloy sputtering target with a high pass through flux (PTF), which is made by a simple melting and casting process.

In an embodiment, the cobalt-iron alloy sputtering target is made by a melting and casting process and consists of an alloy of cobalt, iron and additive metal, wherein the cobalt alloy provides increased pass through flux content in the sputtering target. The additive metal is between 8 at %˜20 at % and is at least one metal selected from the group consisting of tantalum, zirconium, niobium, hafnium, aluminum and chromium.

Other objectives, advantages and novel features of the embodiments of the invention will become more apparent from the following detailed description when taken in conjunction with the accompanying drawings.

### BRIEF DESCRIPTION OF THE DRAWINGS

FIG. 1 is a flow chart of a method for manufacturing a cobalt-iron alloy sputtering target in accordance with an embodiment of the present invention;

FIG. 2 is an image of a conventional target analyzed by in-situ quasi-dynamic back-scattering electron (BSE) microscopy;

FIG. 3 is an image of a target of an embodiment of the present invention analyzed by BSE microscopy; and

FIG. 4 is a chart showing a relationship of Co content in a magnetic sputtering target and permeability.

### DETAILED DESCRIPTION OF THE INVENTION

In one embodiment, a cobalt-iron alloy sputtering target is made by a melting and casting process and consists of cobalt (Co), iron (Fe) and additive metal. The cobalt permits an increased pass through flux (PTF) content in the cobalt-iron alloy sputtering target. The additive metal has a content from 8 at %˜20 at % and is at least one metal selected from the group consisting of tantalum (Ta), zirconium (Zr), niobium (Nb), hafnium (Hf), aluminum (Al) and chromium (Cr).

In one aspect, the increased PTF content is from 10 at % to 35 at % and the content of Fe is from 45 at % to 82 at %.

In another aspect, the increased PTF content is from 60 at % to 70 at % and the content of Fe is from 10 at % to 32 at %.

The cobalt-iron alloy sputtering target has a thickness less than 15 mm and a PTF more than 15%.

In one aspect, the additive metal consists of Ta, Zr, Al and Cr.

In another aspect, the additive metal consists of Ta and Zr.

In yet another aspect, the additive metal consists of Ta.

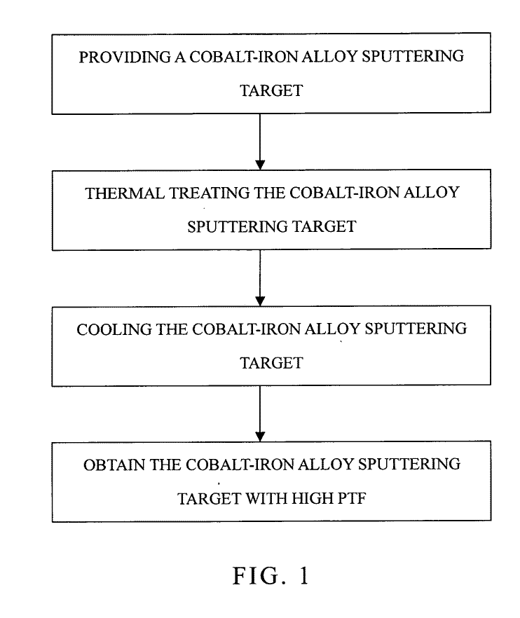

With reference to FIG. 1, a method for manufacturing a cobalt-iron alloy sputtering target with high PTF comprises steps of providing a cobalt-iron alloy sputtering target; thermally treating the cobalt-iron alloy sputtering target; and cooling the cobalt-iron alloy sputtering target to obtain the cobalt-iron alloy sputtering target with high PTF.

The cobalt-iron alloy sputtering target can be made by a melting and casting process and the target consists of cobalt (Co), iron (Fe) and additive metal, wherein the cobalt has an increased pass through flux (PTF) content in the cobalt-iron alloy sputtering target and the additive metal has a content from 8 at %˜20 at % and is at least one metal selected from the group consisting of tantalum (Ta), zirconium (Zr), niobium (Nb), hafnium (Hf), aluminum (Al) and chromium (Cr).

The step of thermally treating the cobalt-iron alloy sputtering target comprises heating the cobalt-iron alloy sputtering target to between 800° C.˜1200° C.

The step of cooling the cobalt-iron alloy sputtering target comprises cooling the cobalt-iron alloy sputtering target with a cooling rate that is equal to or less than 150° C./min.

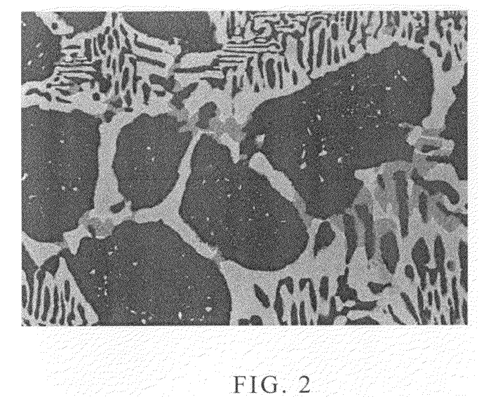

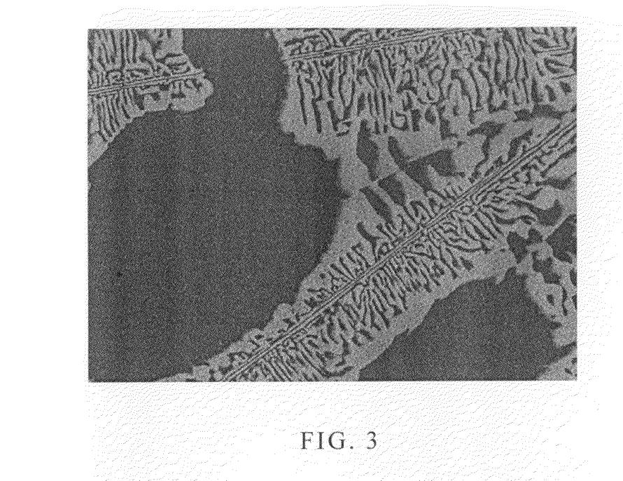

It has been known heretofore that a Co—Fe based alloy sputtering target with a specific amount of additive metal such as Ta, Zr, Nb, Hf, Al, Cr or an alloy thereof provides improved soft magnetic properties. With reference to FIG. 2, however, a conventional Co—Fe based alloy sputtering target that is melted, cast, and then undergoes a conventional high temperature and high pressure process, the additive metal will precipitate within primary crystalline phase and PTF will be decreased. With reference to FIG. 3, a Co—Fe based alloy sputtering target produced by the method described herein, including a thermal treatment between 800° C. and 1200° C. and a cooling step, the additive metal re-dissolves in a matrix phase and PTF will be increased.

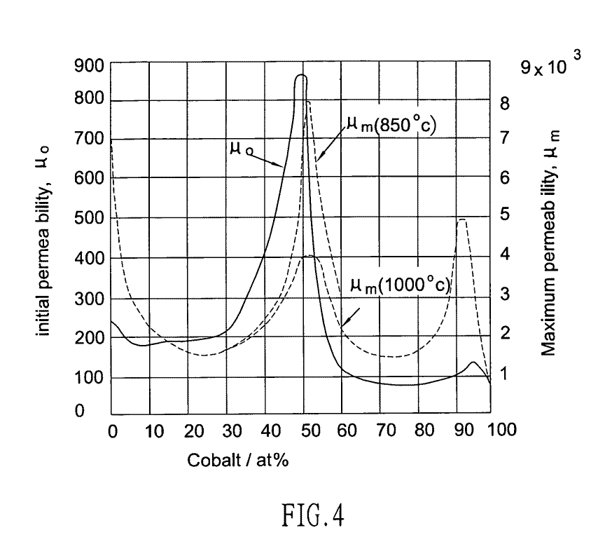

FIG. 4 shows that a cobalt-iron alloy sputtering target has lowest maximum permeability (i.e. highest PTF) when the content of Co is from 10 at % to 35 at % or from 60 at % to 70 at %

### EXAMPLE

Cobalt, iron and additive metal including tantalum, zirconium, niobium, hafnium, aluminum or chromium were mixed according to a specific ratio for each embodiment shown in table 1. The mixture was melted and cast to form a cast ingot. The cast ingot underwent a hot isostatic presses (HIP) process to eliminate shrinkage in the cast ingot. Then, the cast ingot was thermally treated to 900° C. and cooled down to room temperature by air-cooling to obtain a cobalt-iron alloy sputtering target. Finally, the cobalt-iron alloy sputtering target was tested by ASTM F1761. The results are shown in table 1.

TABLE 1

| | | | PTF % | |
|---|---|---|---|---|
| | | Thickness | before thermal | after thermal |
| | Composition | (mm) | treatment | treatment |
| Example 1 | 64Co—28Fe—6Ta—2Zr | 15 | 10 | 20 |
| Example 2 | 28Co—54Fe—16Ta | 15 | 11 | 16 |
| Example 3 | 63Co—27Fe—5Ta—5Zr | 15 | 10 | 17 |
| Example 4 | 65Co—26Fe—5Zr—4Nb | 15 | 11 | 15 |
| Example 5 | 63.5Co—27.5Fe—3.7Ta—4.3Zr—0.5Al—0.5Cr | 15 | 12 | 16 |
| Comparative | 90Co—5Fe—8Ta | 15 | 3 | 9 |
| example 1 | | | | |
| Comparative | 65Co—30Fe—5Ta | 15 | 5 | 10 |
| example 2 | | | | |

According to table 1, the thermal treatment enhances the PTF. Furthermore, when the content of Co is out of the range of the embodiments described herein (as comparative example 1) or a content of the additive metal is out of the range of the present invention (as comparative example 2), even though the cobalt-iron alloy sputtering target undergoes a thermal treatment and keeps a thickness less than 15 mm, the PTF of the cobalt-iron alloy sputtering target cannot be raised higher than 15%. Therefore, the use of a powder metallurgy process to prepare cobalt-iron alloy sputtering targets overcomes the observed disadvantages.

Even though numerous characteristics and advantages of the present invention have been set forth in the foregoing description, together with details of the structure and function of the invention, the disclosure is illustrative only. Changes may be made in detail, especially in matters of shape, size and arrangement of parts within the principles of the invention to the full extent indicated by the broad general meaning of the terms in which the appended claims are expressed.

What is claimed is:

1. A cobalt-iron alloy sputtering target characterized in that:
the cobalt-iron alloy sputtering target is made by melting and casting process and consists of cobalt (Co), iron (Fe) and from 8 at %˜20 at % additive metal, the cobalt having an increased pass through flux (PTF) content in the cobalt-iron alloy sputtering target, the additive metal being at least one metal selected from the group consisting of tantalum (Ta), zirconium (Zr), niobium (Nb), hafnium (Hf), aluminum (Al) and chromium (Cr).

2. The cobalt-iron alloy sputtering target as claimed in claim 1, wherein the increased PTF content is from 10 at % to 35 at % and the content of Fe is from 45 at % to 82 at %.

3. The cobalt-iron alloy sputtering target as claimed in claim 1, wherein the increased PTF content is from 60 at % to 70 at % and the content of Fe is from 10 at % to 32 at %.

4. The cobalt-iron alloy sputtering target as claimed in claim 1, wherein the cobalt-iron alloy sputtering target has a thickness less than 15 mm and a PTF more than 15%.

5. The cobalt-iron alloy sputtering target as claimed in claim 2, wherein the cobalt-iron alloy sputtering target has a thickness less than 15 mm and a PTF more than 15%.

6. The cobalt-iron alloy sputtering target as claimed in claim 3, wherein the cobalt-iron alloy sputtering target has a thickness less than 15 mm and a PTF more than 15%.

7. The cobalt-iron alloy sputtering target as claimed in claim 1, wherein the additive metal consists of Ta, Zr, Al and Cr.

8. The cobalt-iron alloy sputtering target as claimed in claim 1, wherein the additive metal consists of Ta and Zr.

9. The cobalt-iron alloy sputtering target as claimed in claim 1, wherein the additive metal consists of Ta.

10. A method for manufacturing a cobalt-iron alloy sputtering target with high PTF comprising steps of:
providing a cobalt-iron alloy sputtering target by a melting and casting process, the target consisting of cobalt (Co), iron (Fe) and from 8 at %˜20 at % additive metal, wherein the cobalt has an increased pass through flux (PTF) content in the cobalt-iron alloy sputtering target, the additive metal being at least one metal selected from the group consisting of tantalum (Ta), zirconium (Zr), niobium (Nb), hafnium (Hf), aluminum (Al) and chromium (Cr); and
thermally treating the cobalt-iron alloy sputtering target by heating the cobalt-iron alloy sputtering target to between 800° C.˜1200° C. to obtain a cobalt-iron alloy sputtering target with high PTF.

11. The method as claimed in claim 10 further comprising a step of cooling the cobalt-iron alloy sputtering target at a cooling rate that is equal to or less than 150° C./min after thermal treatment of the cobalt-iron alloy sputtering target.

12. The method as claimed in claim 11, wherein the increased PTF content is from 10 at % to 35 at % and the content of Fe is from 45 at % to 82 at %.

13. The method as claimed in claim 11, wherein the increased PTF content is from 60 at % to 70 at % and the content of Fe is from 10 at % to 32 at %.

14. The method as claimed in claim 11, wherein the cobalt-iron alloy sputtering target has a thickness less than 15 mm and a PTF more than 15%.

15. The method as claimed in claim 11, wherein the additive metal consists of Ta, Zr, Al and Cr.

16. The method as claimed in claim 11, wherein the additive metal consists of Ta and Zr.

17. The method as claimed in claim 11, wherein the additive metal consists of Ta.

18. A cobalt-iron alloy sputtering target manufactured by a method comprising steps of:
providing a cobalt-iron alloy sputtering target made by melting and casting process and consisting of cobalt (Co), iron (Fe) and additive metal, wherein the cobalt has an increased pass through flux (PTF) content in the cobalt-iron alloy sputtering target and the additive metal has a content from 8 at %˜20 at % and is at least one metal selected from the group consisting of tantalum (Ta), zirconium (Zr), niobium (Nb), hafnium (Hf), aluminum (Al) and chromium (Cr); and
thermally treating the cobalt-iron alloy sputtering target by heating the cobalt-iron alloy sputtering target to between 800° C.˜1200° C. to obtain the cobalt-iron alloy sputtering target with high PTF.

19. The cobalt-iron alloy sputtering target as claimed in claim 18, comprising a further step of cooling the cobalt-iron alloy sputtering target at a cooling rate that is equal to or less than 150° C./min after thermal treatment of the cobalt-iron alloy sputtering target, the increased PTF content being from 10 at % to 35 at % and the content of Fe being from 45 at % to 82 at %.

20. The cobalt-iron alloy sputtering target as claimed in claim 18, further comprising a step of cooling the cobalt-iron alloy sputtering target at a cooling rate that is equal to or less than 150° C./min after thermal treatment of the cobalt-iron alloy sputtering target, the increased PTF content being from 60 at % to 70 at % and the content of Fe being from 10 at % to 32 at %.
